(19) United States
(12) Patent Application Publication
(10) Pub. No.: US 2008/0178793 A1
(43) Pub. Date: Jul. 31, 2008

(54) Method and system for forming a higher purity semiconductor ingot using low purity semiconductor feedstock

(75) Inventors: Matthias Heuer, Leipzig (DE); Fritz Kirscht, Berlin (DE); Dieter Linke, Berlin (DE); Jean Patrice Rakotoniana, Berlin (DE); Kamel Ounadjela, Belmont, CA (US)

Correspondence Address: HULSEY IP INTELLECTUAL PROPERTY LAWYERS, P.C., 919 Congress Avenue, Suite 919, AUSTIN, TX, 78701, US

(73) Assignee: Calisolar, Inc.

(21) Appl. No.: 11/700,391

(22) Filed: Jan. 31, 2007

(51) Int. Cl. C30B 9/04

(52) U.S. Cl. 117/9; 117/223

(57) ABSTRACT

Techniques for the formation of a higher purity semiconductor ingot using a low purity semiconductor feedstock include associating within a crucible a low-grade silicon feedstock, which crucible forms a process environment of said molten silicon. The process associates with the low-grade silicon feedstock, a quantity of the at least one metal and includes forming within the crucible a molten solution (e.g., a binary or ternary solution) of molten silicon and the metal at a temperature below the melting temperature of said low-grade silicon feedstock. A silicon seed crystal associates with the molten solution within the crucible for inducing directional silicon crystallization. The process further forms a silicon ingot from a portion of the molten solution in association with the silicon seed. The silicon ingot includes at least one silicon crystalline formation grown in the induced directional silicon crystallization process. The resulting silicon ingot has a silicon purity substantially exceeding the silicon purity of said low grade silicon feedstock.

### FIELD

The present disclosure relates to methods and systems for use in the fabrication of semiconductor materials such as silicon. More particularly, the present disclosure relates to a method and system for forming a higher purity semiconductor ingot using low purity semiconductor feedstock.

### DESCRIPTION OF THE RELATED ART

The photovoltaic industry (PV) industry is growing rapidly and is responsible for an increasing amount of silicon being consumed beyond the more traditional uses as integrated circuit (IC) applications. Today, the silicon needs of the solar cell industry are starting to compete with the silicon needs of the IC industry. With present manufacturing technologies, both integrated circuit (IC) and solar cell industries require a refined, purified, silicon feedstock as a starting material.

Materials alternatives for solar cells range from single-crystal, electronic-grade (EG) silicon to relatively dirty, metallurgical-grade (MG) silicon. EG silicon yields solar cells having efficiencies close to the theoretical limit (but at a prohibitive price), while MG silicon typically fails to produce working solar cells. Early solar cells made from polycrystalline silicon achieved relatively low efficiencies near 6%. Efficiency is a measure of the fraction of the energy incident upon the cell to that collected and converted into electric current. However, there may be other semiconductor materials that could be useful for solar cell fabrication.

Cells commercially available today at 24% efficiencies are made possible by higher purity materials and improved processing techniques. These engineering advances have helped the industry approach the theoretical limit for single junction silicon solar cell efficiencies of 31%. In practice nearly 90% of commercial solar cells are made of crystalline silicon.

Several factors determine the quality of raw silicon material that may be useful for solar cell fabrication. These factors may include, for example, transition metal and dopant content and distribution. Transition metals pose a principal challenge to the efficiency of multicrystalline silicon solar cells. Multicrystalline silicon solar cells may tolerate transition metals such as iron (Fe), copper (Cu), or nickel (Ni) in concentrations up to 10¹⁶ cm⁻³, because metals in multicrystalline silicon are often found in less electrically active inclusions or precipitates, often located at structural defects (e.g., grain boundaries) rather than being atomically dissolved.

No simple correlation exists between the total metal content of a semiconductor wafer and cell efficiencies across different ranges of metal or other impurity content. Accordingly, there is a need to both understand and advantageously use the physical properties of metallic impurities in solar cells for improving the processing of low grade silicon feedstock to provide a higher quality silicon ingot.

An improvement of over five orders of magnitude is required from the typical impurity concentrations found in MG-Si to specified limits for silicon feedstock used by the PV industry. Currently many different approaches exist to produce from low grade silicon feedstock a higher grade solar ingot, which may provide the silicon materials for manufacturing PV solar cell silicon wafers.

However, processes providing an attractive combination of reduced processing costs and a high quality silicon ingot are still at an early development stage. One approach that offers promise employs the use of a metal solvent to transform metallurgical grade silicon feedstock to a higher grade of silicon.

One solvent growth technique grows higher purity silicon out of a silicon-aluminum (Si—Al) solution. Analyses of the silicon ingots using this approach have shown metal impurities below two ppma and confirm that the initial concentrations e.g. of iron (Fe) and copper (Cu) were reduced by segregation to the melt.

A further advance to this approach takes the above teachings to achieve a growth of compact single- or multicrystalline silicon ingots using seed crystals from different kinds of silicon feedstock. This approach grows a silicon ingot, for example, from a Si—Al metal solution at growth temperatures ranging e.g. for the Kyropolus and Czochralski (CZ) growth method from 840° C. to 1100° C. In the solvent growth approach, solvent metals may saturate crystals grown from solution at binary (e.g., Si—Al) solubility limits, while reducing other metallic impurities but not downgrading the electrical properties of the resulting silicon (e.g. in the case of Al).

While a well-known and reliable technique for silicon single crystal growth, the traditional CZ process is slow, complex, and has not been adapted to the production of solar material from low grade silicon feedstock so far.

Accordingly, a need exists for a source of silicon ingots to meet the silicon needs of the solar cell industry, which source may not compete with the demands of the IC industry.

A need exists for providing silicon ingots that may ultimately form commercially available solar cells with efficiencies presently achievable using expensive higher purity materials and/or costly processing techniques.

A further need exists for processes that both promote an understand and advantageously use the physical properties of metallic impurities in silicon feedstock for providing higher quality silicon ingots using lower quality silicon feedstock.

### SUMMARY

Techniques are here disclosed for providing a combination of interrelated steps at ingot formation level for ultimately making solar cells. The present disclosure includes a method and system for, and a resulting silicon ingot including higher purity semiconductor material using lower purity semiconductor feedstock. For example, using silicon ingots formed from the processes here disclosed, solar wafers and solar cells with improved performance/cost ratio are practical. In addition, the present disclosure may readily and efficiently combine with metal-related defect removal and modification processes at the wafer level to yield a highly efficient PV solar cell.

According to one aspect of the disclosed subject matter, a semiconductor ingot forming method and associated system are provided for forming a silicon ingot. The method provides the steps and the system includes the appropriate structures for such steps to produce a high quality semiconductor ingot using a low quality semiconductor 20, feedstock. As here disclosed, the material of preference is silicon. However, other forms of semiconductor material are within the scope of the present disclosure. The present disclosure associates within a crucible a low-grade silicon feedstock. The crucible forms a process environment of the molten silicon. Then, a quantity of the at least one metal associates with the low-grade silicon feedstock. The present disclosure forms within the crucible a molten at least binary solution of the molten silicon and the at least one metal at a temperature below the melting temperature of the low-grade silicon feedstock. A silicon seed crystal associates with the at least binary solution at a predetermined location within the crucible for inducing directional silicon crystallization. Then, the present disclosure forms a silicon ingot from a portion of the at least binary solution in association with the silicon seed. The silicon ingot includes at least one silicon crystalline formation grown in the induced directional silicon crystallization. As a result of the present disclosure, the silicon ingot has a silicon purity exceeding the silicon purity of the silicon feedstock. Then, the present disclosure further dissociates the silicon ingot from a remaining portion of the at least binary solution.

These and other advantages of the disclosed subject matter, as well as additional novel features, will be apparent from the description provided herein. The intent of this summary is not to be a comprehensive description of the claimed subject matter, but rather to provide a short overview of some of the subject matter's functionality. Other systems, methods, features and advantages here provided will become apparent to one with skill in the art upon examination of the following FIGURES and detailed description. It is intended that all such additional systems, methods, features and advantages be included within this description, be within the scope of the accompanying claims.

### BRIEF DESCRIPTIONS OF THE DRAWINGS

The features, nature, and advantages of the disclosed subject matter may become more apparent from the detailed description set forth below when taken in conjunction with the drawings in which like reference characters identify correspondingly throughout and wherein:

FIG. 1 is a prior art diagram a known Czochalski silicon ingot formation process;

FIG. 2 illustrates conceptually a process flow for producing a high purity silicon ingot from a silicon-solvent molten solution according to the present disclosure;

FIG. 3 provides a diagram illustrating one embodiment of a process environment for achieving the results of the present disclosure;

FIG. 4 shows a process flow according to the present disclosure for yielding a solar grade silicon ingot;

FIGS. 5 and 6 are phase diagrams for silicon-aluminum and silicon-copper binary solutions;

FIG. 7 presents a diagram of the boundary layer segmentation occurring in association with the disclosed process;

FIG. 8 is a table of typical impurity concentrations in metallurgical silicon, solar grade silicon occurring from the present process, and electronics grade silicon;

FIG. 9 is a table of the possible silicon-metal eutectic systems for which the present disclosure may provide beneficial application; and

FIGS. 10 and 11 illustrate various measure of the present disclosure for increasing the homogeneity of a molten solution for forming a high purity silicon ingot.

### DETAILED DESCRIPTION OF THE SPECIFIC EMBODIMENTS

The method and system of the present disclosure provide a semiconductor ingot formation process for producing a higher purity silicon or semiconductor ingot using a low purity or high impurity silicon or semiconductor feedstock. As a result of using the presently disclosed subject matter, an improvement in the properties of low-grade semiconductor materials, such as metallurgical grade MG or upgraded metallurgical grade silicon (UMG) occurs. Such improvement allows use of UMG silicon, for example, in producing solar cells as may be used in solar power generation and related uses. The method and system of the present disclosure, moreover, particularly benefits the formation of semiconductor solar cells using MG, UMG or other non-electronic grade semiconductor materials. The present disclosure may allow the formation of solar cells in greater quantities and in a greater number of fabrication facilities than has heretofore been possible.

Among various technical advantages and achievements herein described, certain ones of particular note include the ability to reduce the amount of metallic and non-metallic impurities present in a semiconductor ingot such as may be useful in solar cell fabrication.

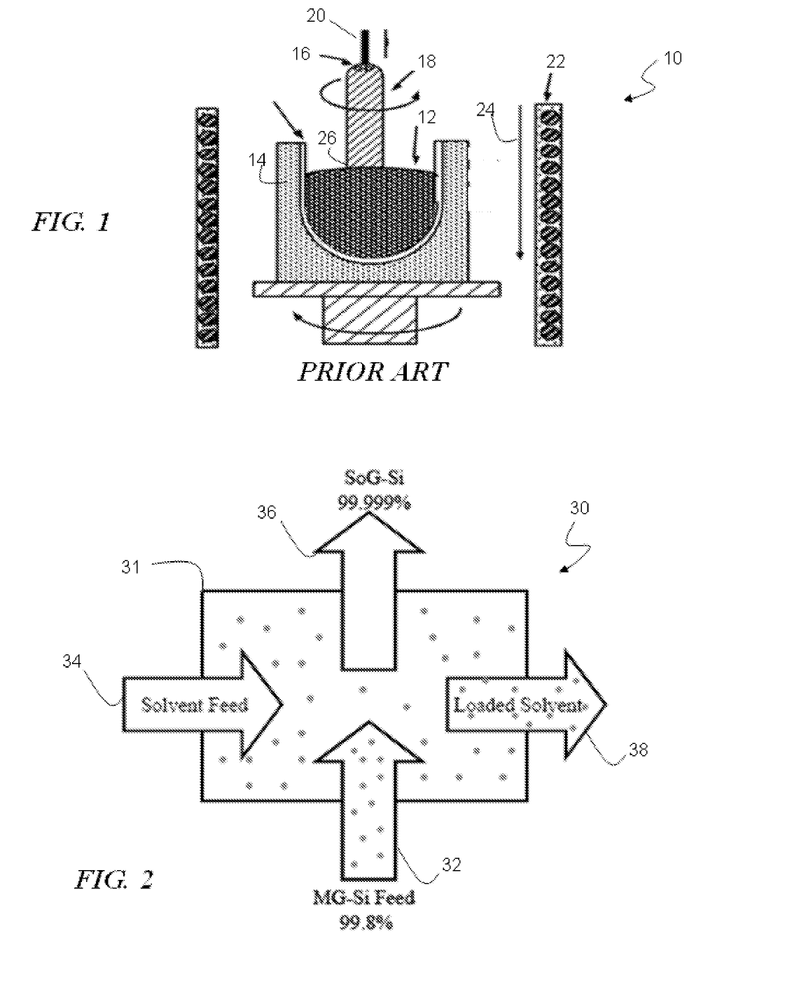

FIG. 1 is a prior art diagram a known Czochalski (CZ) silicon ingot formation process 10. According to the known CZ silicon formation process 10, molten EG silicon 12 is held in fused silica liner 13 of crucible 14. Seed crystal 16 is inserted and then pulled from molten EG silicon melt 12 to form silicon ingot 18. Thus, as seed, which is attached to puller rod 20, moves in the upward direction silicon ingot 18 grows. Heater system 22 provides process control heating so as to great a temperature gradient 24. Temperature gradient 24 results in higher temperatures nearer the bottom of crucible 14 for maintaining a silicon melt 12, while controlling the seed-melt interface 26.

The CZ process to grow single crystal silicon, therefore, involves melting the EG silicon in crucible 13, and then inserting seed crystal 16 on puller rod 20 which is continuously rotating and then slowly removed from melt 12. If the temperature gradient 24 of melt 12 is adjusted so that the melting/freezing temperature is just at seed-melt interface 26, a continuous single crystal silicon ingot 18 will grow as the puller is withdrawn.

The monolithic CZ silicon fabrication process 10 of FIG. 1 starts out with a natural form of silicon; quartzite or SiO₂ that is reacted in a furnace with carbon (from coke and/or coal) to make what is known as metallurgical grade (MG) silicon which is about 98% pure. Approximately 10¹⁴ impurity atoms/cm³ will make major changes in the electrical behavior of a piece of silicon. Since there are about 5×10²² atoms/cm³ in a silicon crystal, this calls for a purity of better than 1 part in 10⁸ or 99.999999% pure material to form EG silicon.

The entire apparatus must be enclosed in an argon atmosphere to prevent oxygen from getting into either melt 12 or silicon ingot 18. Puller rod 20 and crucible 14 are rotated in opposite directions to minimize the effects of convection in the melt. The pull-rate, the rotation rate and temperature gradient 24 must all be carefully optimized for a particular wafer diameter and growth direction. The [111] Direction (along a diagonal of the cubic lattice) is usually chosen for wafers to be used for bipolar devices, while the [100] direction (along one of the sides of the cube) is favored for MOS applications. Currently, wafers are typically 6″ or 8″ in diameter, although 12″ diameter wafers (300 mm) is already industrial standard. Once the boule is grown, it is ground down to a standard diameter (so the wafers can be used in automatic processing machines) and sliced into wafers. The wafers are etched and polished, and move on to the process line.

FIG. 2 illustrates conceptually a process flow for producing a high purity silicon ingot from a silicon-solvent molten solution according to the present disclosure. In particular, crystal growth process 30 involves forming a molten solution 31 from inputs of MG silicon feedstock 32 (e.g., 99.8% pure) or an upgraded metallurgical grade (UMG) silicon feedstock and a solvent 34. Through the now disclosed process, outputs of solar grade silicon (e.g., 99.999% pure) and a loaded solvent 38, which yet includes both silicon and solvent, but to possibly a higher impurity level than molten solution in the beginning 31.

Crystal growth process 30 combines a crystal growth from a melt solution with a directional solidification growth (DS growth) using a seed crystal. An integral part of the present disclosure involves the modification of conventional block casting and directional solidification of silicon in a way that a metallic solvent 34 is added to the MG or UMG silicon feed 32 in an significant amount (e.g. up to 60-70% Al). Such solvent can be Al, Zn, Cu, Ni, Sn, Ag and a combination of these metals. Adding solvent 32 dilutes the impurities in the MG or UMG silicon feedstock 34 and converts the molten solution 31 virtually into a binary or ternary solution.

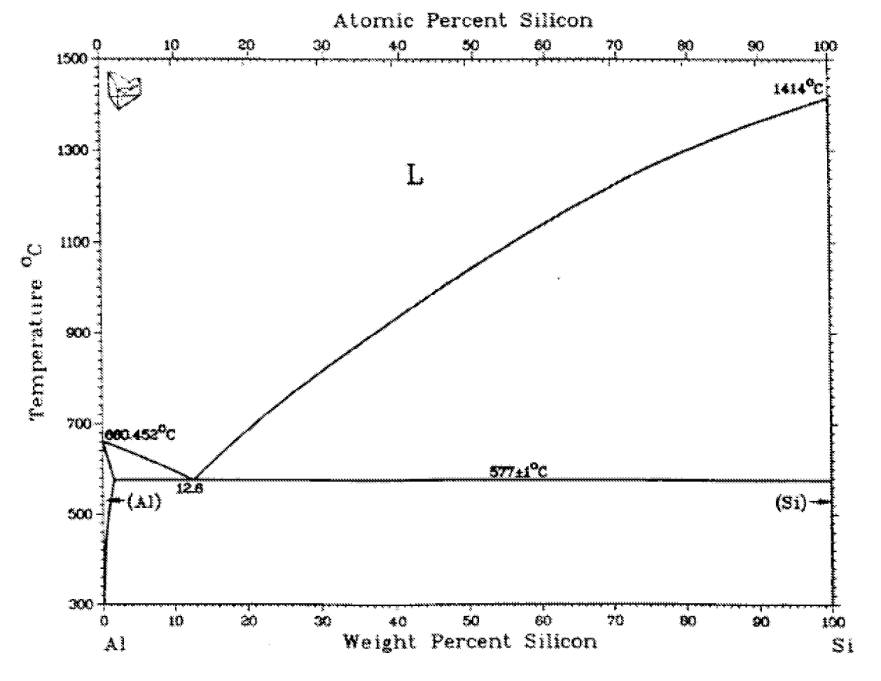

The usable concentrations of solvent 32 are limited by the range in which solar grade silicon 36 grows from molten solution 31 depending on the individual phase diagrams. For example from a molten solution 31 with 800 g silicon and 200 g aluminum, approximately 773 g solar grade 36 can be grown at temperatures between 1300° C. and 660° C. This can be seen through the melting points for the binary silicon-aluminum phase diagram appearing in FIG. 5. The remaining eutectic can be recycled several times lowering the loss of Silicon and the consumption of aluminum. Furthermore, using solvent 32 allows melting silicon feedstock 34 at lower temperatures, thus resulting in additionally saving time and energy. The present disclosure, therefore, provides a major advantage of the disclosed subject matter.

During the “solvent growth casting”, as herein described for producing solar grade silicon 36, the forming silicon will be saturated with the elements used as solvents, while other impurities will be rejected to molton solution 31, due to impurity dilution (in molten solution 31) and a change of the segregation coefficients of (in solar grade silicon 36) which occurs in presence of one or more solvents.

The solvent 32 metals incorporated in the cast solar grade silicon ingot 36 are either not downgrading the electrical properties (such as occurs with an aluminum solvent) or result in a situation, which is easier to manipulate in later gettering steps on the wafer level (e.g., by gettering nickel or copper at a wafer level gettering process). In the case of using nickel or copper as solvent 32, the incorporation of gettering resistant metal species (e.g, iron or titanium) is replaced by formation of easily dissolvable clusters of fast diffusers. Furthermore a combination of copper and nickel as solvent and the incorporation of these elements into the growing silicon may lead to the formation of precipitates which under certain circumstances may, in fact, serve as active gettering sites.

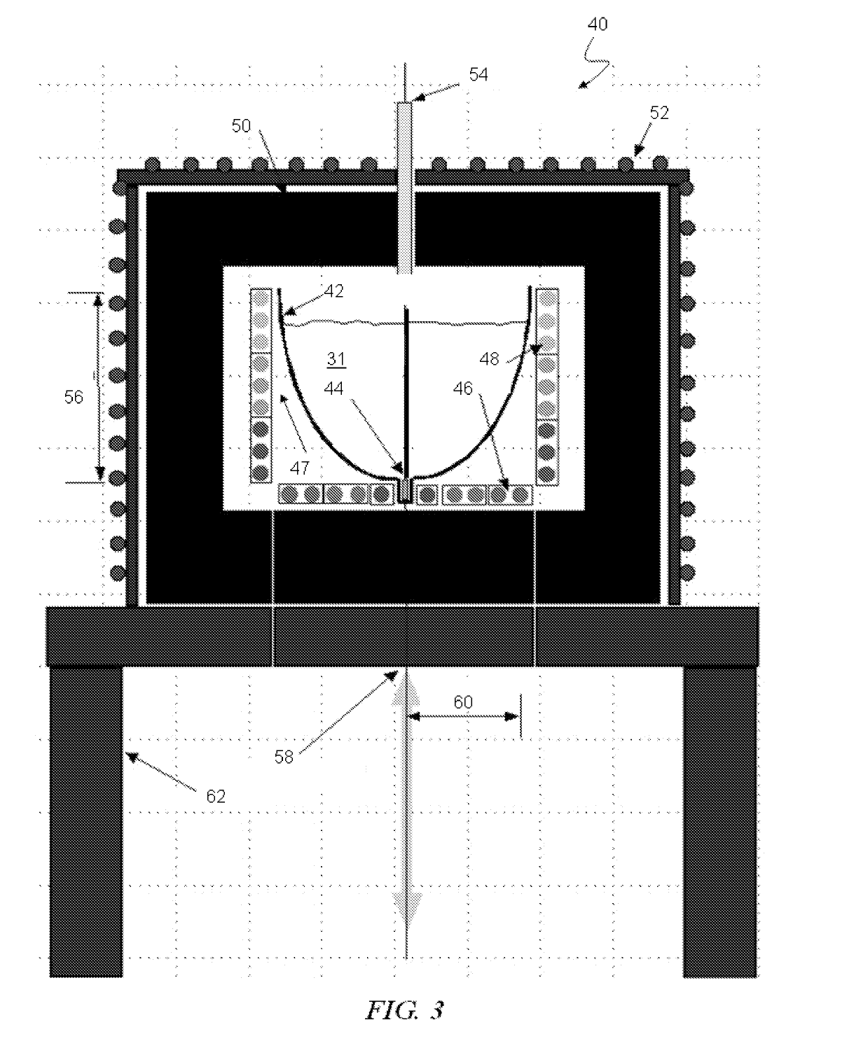

FIG. 3 provides a diagram illustrating one embodiment of a process environment 40 for achieving the results of the present disclosure. In FIG. 3, Al—Si molten solution 31 within corundum crucible 42. Silicon seed 44 is positioned at the bottom of corundum crucible 42 for initiating a directional solidification silicon crystal formation to produce solar grade silicon 36. Heating zones 46, 47, 48 surround the sides and bottom of corundum crucible 42. CBCF-isolation chamber 50 further establishes a process environment in conjunction with corundum crucible 42 for temperature control and to establish a process atmosphere. Water cooling system 52 surrounds CB CF-isolation 50, which camera 54 penetrates to allow observation of molten solution 31. Process environment 40 has a height 56, which corundum crucible 42 spans vertically. However, for enhanced process control dropping mechanism 58, which has a radius 60 may move vertically downward within lower frame 62 to place different portions of corundum crucible to different temperature heating zones 47 and 48 more rapidly or at in more varying ways that can direct heating zone control.

The present embodiment uses as a crucible, corundum crucible 42 to allow for the use of aluminum as a solvent material. Otherwise, molten solution 31, when using aluminum as the solvent material will destroy the crucible.

Solar grade silicon ingot 36 may be grown in a water-cooled, induction-heated, processing environment 40, which provides a sealed growth chamber having a vacuum of, for example, below 1×10⁻³ Torr and cycle purged with argon to 10 psig several times to expel any oxygen remaining in the chamber. Heating zones 46, 47, and 48 may be heated by a multi-turn induction coil in a parallel circuit with a tuning capacitor bank.

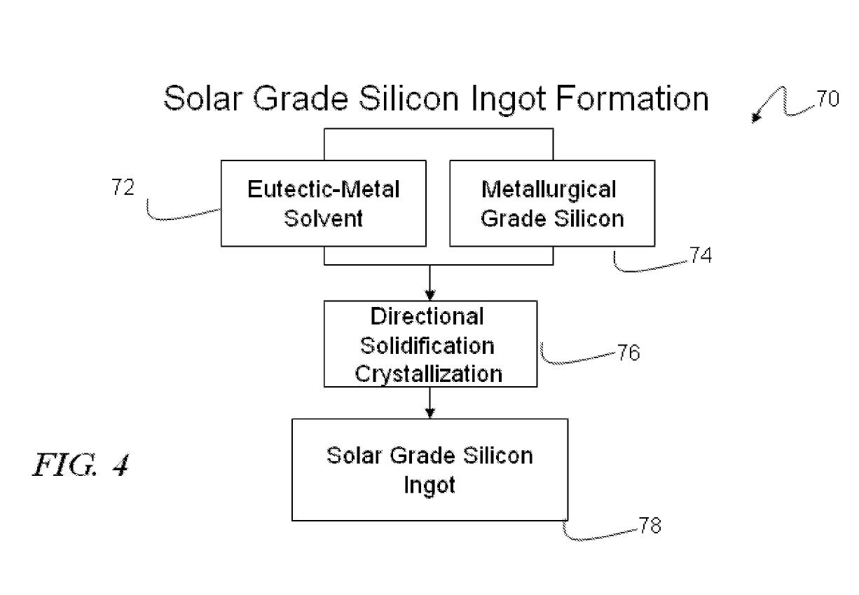

The present disclosure may combine with metal related defect engineering on the wafer level. On the other hand, the processing steps here disclosed may be independent from wafer level process improvement. FIG. 4 shows a process flow 70 according to the present disclosure for yielding solar grade silicon ingot 36. Beginning at step 72, a eutectic metal solvent 32 and metallurgical grade or UMG silicon 34 are added to form molten solution 36, as described above and indicated by step 74. Then, using the process environment 40 of FIG. 3, directional silicon crystallization occurs at step 76 to yield solar grade silicon ingot 36.

Once directional solidification step 76 terminates there may be different options for processing the remaining molten solution, i.e., loaded solvent 38. One option may be to pour or drain off the molten loaded solvent 38, leaving only solar grade silicon ingot 36 within corundum crucible 42. However, another option may be to continue with the solidification of the molten solution at a lower process temperature. Then, the solid portion of loaded solvent may be simply physically removed from the solar grade silicon ingot 36.

Process flow 30 involves the freezing of an alloy in the silicon-metal eutectic system of molten solution 31. Metallurgical or UMG silicon feedstock 34 is dissolved in molten solution 31 and heated. Upon slow cooling from the molten state of molten solution 31, the separation of solar grade silicon from the liquid molten solution 31 occurs. As cooling continues, the liquid becomes depleted of silicon and the composition of molten solution 31 shifts toward the eutectic composition of loaded solvent 38. Eventually, the eutectic point is reached for solar grade silicon ingot 36, and further cooling results in eutectic solidification of the remaining loaded solvent.

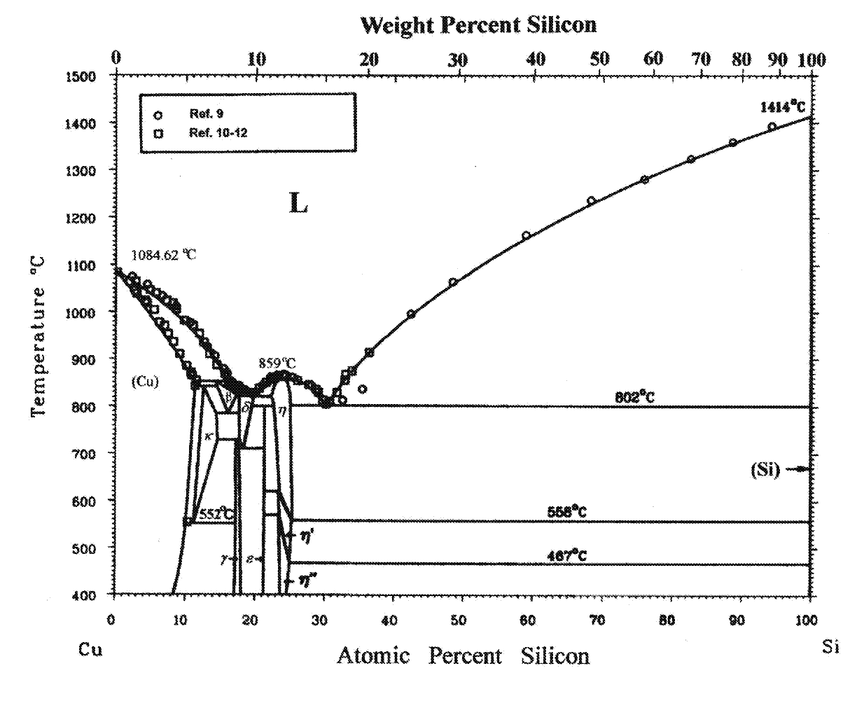

FIGS. 5 and 6 are phase diagrams for silicon-aluminum and silicon-copper binary solutions. An investigation of silicon binary phase diagrams for simple eutectic systems identifies six metal solvent candidates. In principle, any silicon-metal binary system could be considered, as long as solidification takes place along the liquidus curve close to the pure silicon phase. Binary eutectic systems offer a straightforward interpretation of impurity segregation. Complicated phase fields, inter-metallic compositions, and the immiscibility of some liquids limit the compositions and temperatures for silicon growth. Solvent selection is restricted to metals that form binary eutectic systems with silicon in order to conduct solidification along lower liquidus temperatures in comparison with peritectic or multi-phase systems.

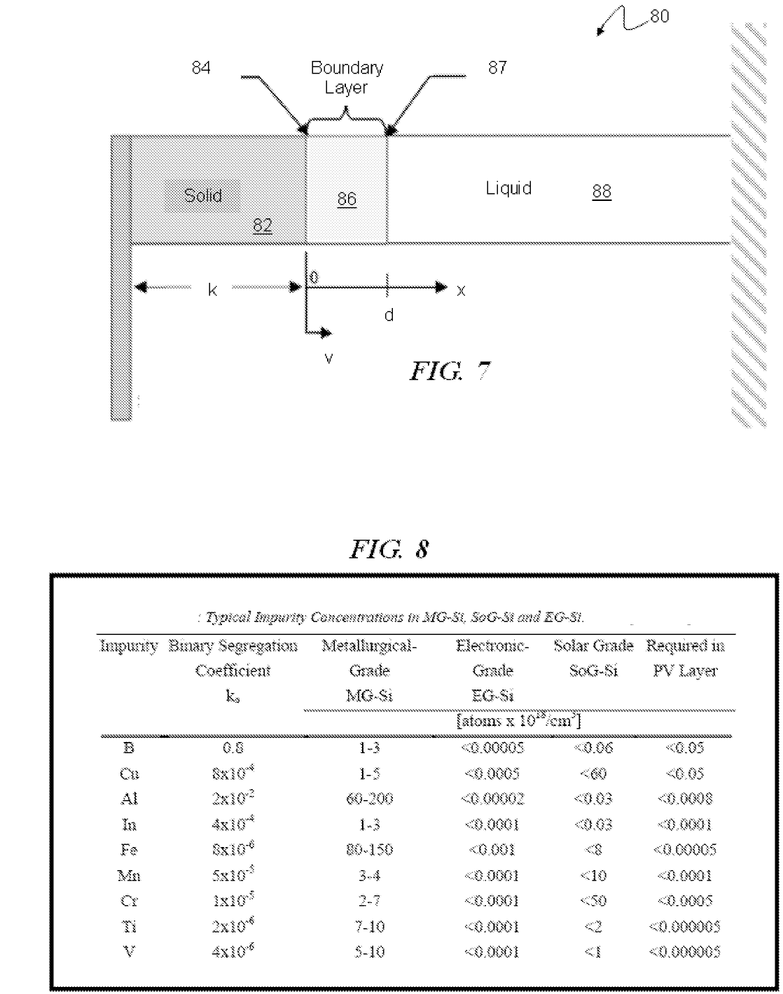

FIG. 7 presents diagram 80 of the boundary layer segmentation occurring in association with the disclosed process. Boundary layers segmentation diagram 80 depicts the directional solidification process 76 of FIG. 4, wherein molten solution 31 transitions to become solar grade silicon 36. From silicon seed 44, solar grade silicon region 82, having a width 1, includes interface 84 with eutectic boundary layer 86. Boundary layer 86 shows a distance, d, and interface 87 with liquid phase 88 of molten solution 31. Solute movement in a liquid phase 88 involves convection as well as diffusion. In general, diffusivities are much higher in liquids than in solids. Free and forced molten solution 31 convection creates concentration and temperature gradients within finite boundary layer 86 near solid/liquid interface 84. The thickness of boundary layer 86 may exist either in a steady-state configuration or as an unstable, time-dependent relation.

The driving force for solidification is the difference between chemical potentials in the solid state 82 and liquid state 88. The chemical potential of a species depends on temperature, pressure, and concentration. Modifying one or all of these parameters from an initial equilibrium state will cause an imbalance in the chemical potential of the entire system. Crystallization of solid silicon is possible when the free energy of the solid state 82 is lower than that of liquid state. A solution at an equilibrium temperature has a driving force for solidification proportional to the amount of under-cooling.

The lower free energy that is created by solidification of solar grade silicon 36 from molten solution 31 results from the difference between free energies in solid state 82 and the liquid 88 from which solar grade silicon 36 is growing. The free energy of solidification serves as barrier for attaching an atom to the crystal. Spatial separations between the solid state 82 and boundary state 86 create interfacial barrier 84 energy that is overcome by the adsorption of atoms at the solid state 82 surface, and lowers the overall free energy of the system.

Crystal growth of solar grade silicon 36 occurs as the balance between equilibrium temperature gradients across boundary layer 84 and the transfer of this equilibrium in such a way that the interface moves in a controlled manner. The stability of the boundary layer 86, at least locally, determines the purity of growing crystal. Single crystal growth is extremely sensitive to fluctuations in boundary layer 86. Creating a boundary layer 86 when growing crystals from solution is even more critical. The high solvent concentration used in solution growth restricts diffusion of silicon solute to boundary layer 86. In a binary solution, the requirement for planar solidification stability is a function of the thermal gradient in liquid state 82 and the solidification velocity. When the ratio of temperature gradient to growth rate is lower than the diffusivity of solute to the solid/liquid interface, constitutional super-cooling takes place. Constitutional super-cooling causes the breakdown of a boundary layer 86 leading to cellular or dendritic growth. Interface instability is disrupted by solvent concentration build up that results from limited solute diffusion to the interface. Breakdown is avoided by creating a high thermal gradient in the furnace hot zone and by maintaining a relatively low growth rate.

Boundary layer 86 under steady-state growth conditions is constrained by boundary conditions at the two interfaces 84 and 87 defining the layer of thickness, d. At the solid/liquid interface, the composition in the bulk liquid must equal that in the boundary layer, and the liquid concentration must equal the bulk concentration at the edge of boundary layer 86. Using these conditions, impurity segregation expressions describe the ratio of concentrations found in the liquid to that found in the crystal are formed and therefore control the resulting purity of solar grade silicon 36.

FIG. 7 illustrates the boundary layer formation near solid/liquid interface 87. Note that the crucible wall location is approximated to be at x=, and the progression of crystal diameter growth forces the axis where x=0 to move at velocity, v. The partition ratio together with respect to the thermal gradient present strongly influences crystal perfection. At equilibrium, k only depends on thermodynamic quantities that are not a function of orientation. When out of equilibrium, k has a crystallographic component. Furthermore, ideal solutions lead to an independent k, while regular solutions do not because of the dependence on the liquidus slope. The degree of segregation depends on the transport mechanism in the liquid just prior to freezing. The present disclosure takes into consideration these dynamic parameters in the directional solidification of solar grade silicon ingot 36 from seed crystal 44.

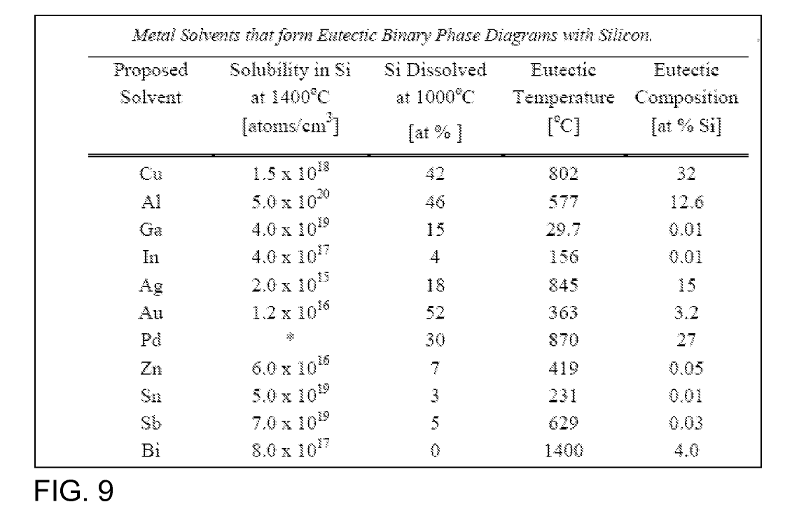

FIG. 8 is a table of typical impurity concentrations in metallurgical silicon, solar grade silicon, and electronics grade silicon. FIG. 9 lists the possible silicon-metal eutectic systems for which the present disclosure may provide beneficial application. The solubility of the metal in silicon at 1400° C. also appears in FIG. 9 to show the maximum solvent concentration that may remain in solar grade silicon 36 at silicon's melting temperature. A low solubility of the impurity in the silicon 36 is desirable, as higher impurity concentrations may require further reductions to effectively control dopant densities. Al, Sn, Sb, and Ga solvents all exhibit high solid solubility in silicon; however, it may be possible to reduce incorporation into the solid solar grade silicon 36, if solidification takes place below 1400° C.

The benefit of using metal eutectic solutions to lower liquidus temperatures from the melting point of pure silicon at 1410° C. is reduced furnace power consumption, less expensive heating elements, and faster heating and cooling cycles. Solvent 32 composition ranges selected from binary phase diagrams may achieve melting temperatures between 800° C. and 1100° C. Silicon solidification is conducted on the silicon-rich side of a eutectic composition. The slope of the liquidus curve is confined by the melting point of silicon and the eutectic temperature, while the melting point of silicon remains unchanged for each system.

FIG. 9 gives the eutectic composition and temperature for the molten solution 31 binary system. Low melting solvents amplify the disparity between the silicon melting point and the eutectic temperature. Also in FIG. 9 is the relative atomic percentage of silicon that is dissolved by a particular solvent. The percent silicon dissolved by a solvent correlates the amount of metallurgical-grade or UMG silicon refined by solution growth to the solvent used. Solvents that exhibit lower ratios require more solvent to purify less silicon, and practicality dictates that a good solvent for solution growth poses the ability to dissolve appreciable amounts of silicon.

Referring to FIG. 9 in conjunction with FIGS. 5 through 6 show, Cu and Al dissolve sufficient amounts of silicon at the representative growth temperature of 1000° C. and provide attractive eutectic liquid-solid temperature characteristics to make them possible solvent candidates for use in the presently disclosed process.

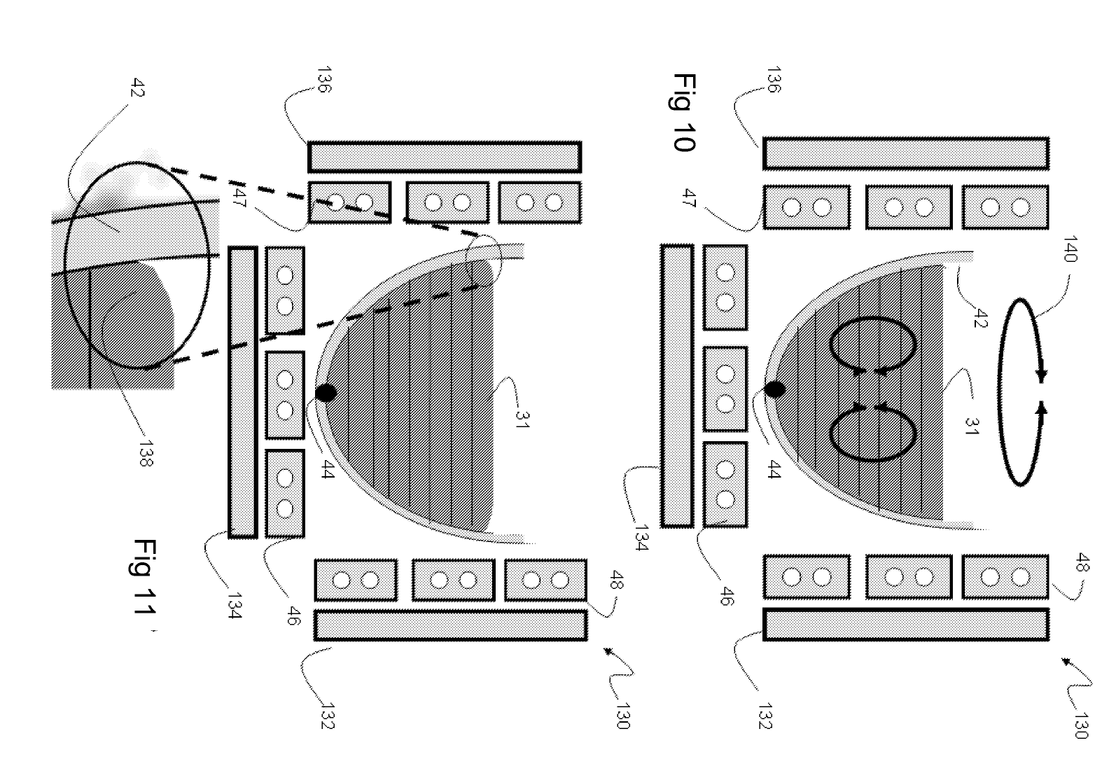

FIGS. 10 and 11 show development of the processing and process environment for forming solar grade silicon ingot 36 that may further increase the homogeneity of molten solution 31. Convective stirring of molten solution 31 occurs in all crystal growth techniques. Natural convection occurs in the presence of a gravitational field, a density gradient, and a surface tension gradient. Forced convection arises from the presence of concentration, temperature, and shear stress gradients and in the presence of any magnetic fields. Solution growth carried out in this investigation contains all of the above contributors to convection. In addition to natural convection, the presence of solvent and impurity atoms in molten solution 31 during silicon crystal growth causes a concentration gradient.

In addition to the heating zones 46, 47, and 48 as also shown in FIG. 3, above, process environment 130 shows magnetic coils 132, 134, and 136, which provide a magnetic field within molten solution 31. The result becomes the magnetohydrodynamic stirring by the induction coils, which may further add to the magnetic fields inherently arising from heating coils that may exist in heating zones 46, 47, and 48.

At the onset of silicon crystallization, there is the need to optimize the convective flow to reduce stress in the crystallization process and to influence the form of the interface between melt and solid. Convective flow optimization may occur through the use of countervailing inductive forces from magnetic coils 132, 134, and 136 to minimize or eliminate any inductive forces from heating zones, 46, 47, and 48.

In addition to the optimization of convective flow within molten solution 31, the present disclosure provides the ability to get the formation of optimized thermal gradients that may exist or arise in molten silicon 31. By introducing a compensating heating or cooling in corundum crucible 42, it is possible to control the convective flow. The different controllers for the heating zones allows for a more straight line of convective flow.

The magnetic field control for countervailing convective flow may also be beneficial to optimize thermal gradients in molten solution 31. The time requirements driven by the quantity of molten silicon, the temperature and other process parameters may dictate which type of response should occur at the time of silicon crystallization.

In addition to inducing convective heat transfer, process environment shows the use of a rotational force 140, which may be introduced to produce a sheer force within corundum crucible 42 and seed are rotated. A shear stress may also occur, as FIG. 11 shows, along crucible wall as solar grade silicon ingot 36 formation occurs.

The present disclosure promotes a leveling or straightening of the upper surface of molten solution 31 as silicon crystallization occurs. By making the crystallized silicon as straight as possible a minimization of shear and other stress occurs, thereby preventing unwanted crystallizations away from seed crystal 44. Thus, the present disclosure calls for a maximum isothermal line and avoidance of meniscus or curved region 138. Achieving such a straight line occurs, as discussed above, through the appropriate controls of heating zones 46, 47, and 48, the use of magnetic coils 132, 134, and 136, as well as other forms of energy.

In the radial direction, we have a radial temperature gradient. In the radial direction, thermally induced mechanical stresses may also arise. In avoiding the existing of stress-causing, radial temperature gradients, the present disclosure may likewise employ coordinated and compensating uses of heating zones 46, 47, and 48, magnetic coils 132, 134, and 136, as well as other forms of energy.

Yet a further approach for controlling and minimizing stresses in the formation of solar grade silicon ingot 36 varies the crucible material. In addition, the type of crucible may vary, not only the contact with the solidifying materials may make a change, but also in the ways in which movement within crucible 42 may take place.

In summary, the disclosed subject matter provides a method and system for forming silicon ingot 36 by associating within crucible 42 a low-grade silicon feedstock 34. Crucible 42 forms a portion of the process environment 40 for molten solution 31. Molten solution 31 also includes a quantity of the at least one metal (e.g. aluminum). The present disclosure forms within crucible 42 a molten solution 31 at a temperature below the melting temperature of the low-grade silicon feedstock 34. The process further associates a silicon seed crystal with molten solution 31 for inducing a directional silicon crystallization process. Solar grade silicon ingot 36 forms from a portion of molten solution 31. Solar grade silicon ingot 36 has a silicon purity exceeding the silicon purity of metallurgical grade silicon feedstock 34.

The processing features and functions described herein for forming a high purity silicon ingot from low purity Although various embodiments which incorporate the teachings of the present disclosure have been shown and described in detail herein, those skilled in the art may readily devise many other varied embodiments that still incorporate these teachings. The foregoing description of the preferred embodiments, therefore, is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein, but is to be accorded the widest scope consistent with the principles and novel features disclosed herein.

What is claimed is:

1. A method for forming a higher purity silicon ingot from a low purity silicon feedstock, comprising the steps of:
associating within a crucible a low-grade silicon feedstock, said crucible forming a process environment of said molten silicon;
associating with said low-grade silicon feedstock a predetermined quantity of at least one metal;
forming within said crucible a molten at least binary solution of said molten silicon and said at least one metal at a temperature below the melting temperature of said low-grade silicon feedstock;
associating a silicon seed crystal with said at least binary solution at a fixed predetermined location within said crucible for inducing a directional silicon crystallization process; and
continuing said directional silicon crystallization process for forming a higher purity silicon ingot from a portion of said at least binary solution in association with said silicon seed and having a silicon purity substantially exceeding the silicon purity of said silicon feedstock.

2. The method of claim 1, further comprising the step of controlling said process environment by controlling the temperature of said at least binary solution.

3. The method of claim 1, further comprising the step of associating a quantity of a metal with said molten silicon for forming at least binary solution of said molten silicon and said metal, said metal comprising a metal from the group consisting essentially of aluminum, copper, zinc, tin, silver and nickel.

4. The method of claim 1, wherein said at least binary solution comprises an at least ternary solution, said at least ternary solution comprising said molten silicon said metal, and a third element.

5. The method of claim 1, further comprising the step of forming said silicon ingot from a portion of said at least binary solution by spatially controlling the temperature of said at least binary solution proximate to said silicon seed crystalline formation.

6. The method of claim 1, further comprising the step of positioning said silicon seed crystalline formation in association with at least binary solution for controlling the crystal growth direction of said at least one silicon crystalline formation.

7. The method of claim 1, further comprising the step of forming said at least one silicon crystalline formation as a single crystal silicon formation.

8. The method of claim 1, further comprising the step of forming said at least one silicon crystalline formation as a multi-crystalline silicon formation.

9. The method of claim 1, further comprising the step of controlling said process environment using a plurality of crucible heaters associated with said crucible.

10. The method of claim 1, further comprising the step of controlling said process environment by programmably controlling a plurality of crucible heaters associated with said crucible.

11. The method of claim 1, further comprising the step of yielding from said at least binary solution a silicon ingot having a reduced transition metal concentration relative to said silicon feedstock.

12. The method of claim 1, further comprising the step of yielding from said at least binary solution a silicon ingot have a reduced boron concentration relative to said silicon feedstock.

13. The method of claim 1, further comprising the step of draining said remaining portion of said at least binary solution for yielding said silicon ingot within said crucible.

14. The method of claim 1, further comprising the step of removing said silicon ingot from said remaining portion of said at least binary solution for yielding said remaining portion of said at least binary solution within said crucible.

15. The method of claim 1, further comprising the step of forming at least one silicon wafer from silicon ingot.

16. The method of claim 15, further comprising the step of forming at least one solar cell from at least one silicon wafer.

17. The method of claim 1, wherein said crucible comprises an aluminum oxide material for preventing damage to said crucible from said molten solution.

18. The method of claim 1, wherein said silicon feedstock comprises metallurgical silicon.

19. The method of claim 1, further comprising the step of controlling the homogeneity of said molten solution using at least one magnetohydrodynamic controller.

20. The method of claim 1, further comprising the step of controlling the homogeneity of said molten solution using a mechanical device, said mechanical device for moving said crucible and, thereby, agitating said molten solution.

21. A system for forming a silicon ingot from a low-grade silicon feedstock, comprising:
a crucible for receiving a low-grade silicon feedstock, said crucible forming a process environment of said molten silicon;
a predetermined quantity of at least one metal associating with said low-grade silicon feedstock within said crucible;
a heat source for forming within said crucible a molten solution at least binary of said molten silicon and said at least one metal at a temperature below the melting temperature of said low-grade silicon feedstock;
a silicon seed crystal within said at least binary solution and positioned for inducing a directional silicon crystallization process;
crucible control means for controlling said directional silicon crystallization process to form of a silicon ingot from a portion of said at least binary solution in association with said silicon seed so that said silicon ingot comprises at least one silicon crystalline formation grown in said induced directional silicon crystallization process, said silicon ingot having a silicon purity exceeding the silicon purity of said silicon feedstock.

22. The system of claim 21, further comprising heater control circuitry for said process environment by controlling the temperature of said at least binary solution.

23. The system of claim 21, wherein said quantity of a metal for associating with said molten silicon comprises a metal from the group consisting essentially of aluminum, copper, zinc, tin, silver and nickel.

24. The system of claim 21, wherein said at least binary solution comprises an at least ternary solution, said at least ternary solution comprising said molten silicon said metal, and a third element.

25. The system of claim 21, further comprising the spatial temperature control circuitry for spatially controlling the temperature of said at least binary solution proximate to said silicon seed crystalline formation.

26. The system of claim 21, further comprising a crucible positioning mechanism for positioning said silicon seed crystalline formation in association with said at least binary solution for controlling the crystal growth direction of said at least one silicon crystalline formation.

27. The system of claim 21, further comprising the step of forming said at least one silicon crystalline formation as a single crystal silicon formation.

28. The system of claim 21, further comprising the step of forming said at least one silicon crystalline formation as a multi-crystalline silicon formation.

29. The system of claim 21, further comprising the step of controlling said process environment using a plurality of crucible heaters associated with said crucible.

30. The system of claim 21, further comprising the step of controlling said process environment by programmably controlling a plurality of crucible heaters associated with said crucible.

31. The system of claim 21, further comprising the step of yielding from said at least binary solution a silicon ingot having a reduced transition metal concentration relative to said silicon feedstock.

32. The system of claim 21, further comprising the step of yielding from said at least binary solution a silicon ingot have a reduced boron concentration relative to said silicon feedstock.

33. The system of claim 21, further comprising the step of draining said remaining portion of said at least binary solution for yielding said silicon ingot within said crucible.

34. The system of claim 21, further comprising cutting means for removing said silicon ingot from said remaining portion of said at least binary solution for yielding said remaining portion of said at least binary solution within said crucible.

35. The system of claim 21, further comprising wafer forming means for forming at least one silicon wafer from silicon ingot.

36. The system of claim 35, further electrical circuitry associated with said silicon wafer for forming at least one solar cell from at least one silicon wafer.

37. The system of claim 21, wherein said crucible comprises an aluminum oxide material for preventing damage to said crucible from said molten solution.

38. The system of claim 21, wherein said silicon feedstock comprises at least one form of metallurgical silicon.

39. The system of claim 21, further comprising at least one magnetohydrodynamic controller for controlling the homogeneity of said molten solution using.

40. The system of claim 21, further comprising a mechanical crucible movement device for moving said crucible and, thereby, agitating said molten solution for controlling the homogeneity of said molten solution.

41. A higher purity silicon ingot formed from a low purity silicon feedstock by performing the steps of:
associating within a crucible a low-grade silicon feedstock, said crucible forming a process environment of said molten silicon;
associating with said low-grade silicon feedstock a quantity of said at least one metal
forming within said crucible a molten at least binary solution of said molten silicon and said at least one metal at a temperature below the melting temperature of said low-grade silicon feedstock;
associating a silicon seed crystal with said at least binary solution at a fixed predetermined location within said crucible for inducing a directional silicon crystallization process;
continuing said directional silicon crystallization process for forming a higher purity silicon ingot from a portion of said at least binary solution, said higher purity silicon ingot comprising at least one silicon crystalline formation grown in said induced directional silicon crystallization process, said higher purity silicon ingot having a silicon purity substantially exceeding the silicon purity of said silicon feedstock.
